(19) United States
(12) Patent Application Publication
(10) Pub. No.: US 2025/0393379 A1
(43) Pub. Date: Dec. 25, 2025

(54) DISPLAY DEVICE AND DISPLAY SYSTEM INCLUDING THE SAME

(71) Applicant: Samsung Display Co., LTD., Yongin-si (KR)

(72) Inventor: Byeong Kyun CHOI, Yongin-si (KR)

(73) Assignee: Samsung Display Co., LTD., Yongin-si (KR)

(21) Appl. No.: 19/036,580

(22) Filed: Jan. 24, 2025

(30) Foreign Application Priority Data
Jun. 21, 2024 (KR) 10-2024-0081173
Aug. 26, 2024 (KR) 10-2024-0114156

(51) Int. Cl. H10H 29/856

(52) U.S. Cl. CPC H10H 29/856

(57) ABSTRACT

A display device includes a substrate, a pixel circuit layer disposed on the substrate, a display element layer disposed on the pixel circuit layer and including a first light-emitting element and a second light-emitting element different from the first light-emitting element, a reflective part disposed between the first light-emitting element and the second light-emitting element, and a lens array including a first lens disposed on the first light-emitting element and a second lens disposed on the second light-emitting element. An end portion of the reflective part includes a first reflective part and a second reflective part extending symmetrically with respect to the first reflective part.

### CROSS-REFERENCE TO RELATED PATENT APPLICATIONS

This application claims priority under 35 U.S.C. § 119 to and benefits of Korean patent Application No. 10-2024-0081173 filed on Jun. 21, 2024, and Application No. 10-2024-0114156 filed on Aug. 26, 2024 in the Korean Intellectual Property Office, the entire contents of which are incorporated herein by reference.

### BACKGROUND

### 1. Technical Field

Embodiments relate to a display device and a display system including the display device.

### 2. Description of the Related Art

As information technology develops, the importance of display devices, which are a connecting medium between users and information, is increasing. Accordingly, the use of display devices such as liquid crystal display devices, and organic light emitting display devices is increasing.

Meanwhile, light output from a display panel included in a display device may be refracted by the internal configuration of the display panel, and thus the brightness of an image expressed by the display device may be reduced. Further, light emission efficiency of an image output from the display panel may be reduced.

The content set forth above is only intended to help understanding of the background of the technical ideas of the disclosure and, therefore, it should not be understood as corresponding to prior art known to those skilled in the art to which the disclosure pertains.

### SUMMARY

A technical object to be achieved is to provide a display device and a display system in which the light emission efficiency of images output from a plurality of sub-pixels is improved by disposing a reflective part between the plurality of sub-pixels.

However, embodiments are not limited to those set forth herein. The above and other embodiments will become more apparent to one of ordinary skill in the art to which the disclosure pertains by referencing the detailed description of the disclosure given below.

A display device according to an embodiment includes: a pixel circuit layer disposed on the substrate; a display element layer disposed on the pixel circuit layer and including a first light-emitting element and a second light-emitting element different from the first light-emitting element; a reflective part disposed between the first light-emitting element and the second light-emitting element; and a lens array including a first lens disposed on the first light-emitting element and a second lens disposed on the second light-emitting element. An end portion of the reflective part includes a first reflective part and a second reflective part extending symmetrically with respect to the first reflective part.

The first lens may have a convex shape having a first curvature, and the first reflective part may have a bent shape having a second curvature so as to be adjacent to the first lens.

A size of the first curvature and a size of the second curvature may be same as each other.

A size of the first curvature and a size of the second curvature may be proportional.

The reflective part may be in contact with an upper surface of the pixel circuit layer.

The display element layer may include an overcoat layer disposed on the first light-emitting element and the second light-emitting element.

The overcoat layer may include a dielectric.

The reflective part may extend in a direction and penetrate the overcoat layer.

The lens array may be disposed on the overcoat layer.

Each of the first light-emitting element and the second light-emitting element may include a first electrode disposed on the pixel circuit layer and a second electrode overlapping the electrode, and the lens array may be directly disposed on a third electrode.

The end portion of the reflective part may extend higher than a height of the lens array in cross-section.

The display device may further include a support part that supports the first reflective part and the second reflective part of the reflective part.

The support part may have light transparency.

The pixel circuit layer may include one or more transistors, and the one or more transistors may include a complementary metal-oxide-semiconductor.

The first light-emitting element and the second light-emitting element may be micro light emitting diodes (LED).

Another aspect of the disclosure relates to a display system. A display system according to an embodiment may include a processor that provides input image data to a display device; and the display device that displays an image based on the input image data. The display device includes a substrate; a pixel circuit layer disposed on the substrate; a display element layer disposed on the pixel circuit layer and including a first light-emitting element and a second light-emitting element different from the first light-emitting element; a reflective part disposed between the first light-emitting element and the second light-emitting element; and a lens array including a first lens disposed on the first light-emitting element and a second lens disposed on the second light-emitting element. An end portion of the reflective part may include a first reflective part and a second reflective part extending symmetrically with respect to the first reflective part.

The first lens may have a convex shape having a first curvature, and the first reflective part may have a bent shape having a second curvature so as to be adjacent to the first lens.

A size of the first curvature and a size of the second curvature may be same as each other.

A display device and a display system according to the disclosure may improve the light emission efficiency of images output from a plurality of sub-pixels by disposing a reflective part between the plurality of sub-pixels.

Effects according to embodiments are not limited to those examples above, and more diverse effects are included in the description.

### BRIEF DESCRIPTION OF THE DRAWINGS

FIG. 1 is a schematic block diagram illustrating an embodiment of a display device.

FIG. 2 is a schematic block diagram illustrating an embodiment of any one of sub-pixels of FIG. 1.

FIG. 3 is a schematic plan view illustrating an embodiment of a display panel of FIG. 1.

FIG. 4 is a schematic cross-sectional view illustrating an embodiment of the display panel of FIG. 3.

FIG. 5 is a schematic plan view illustrating an embodiment of any one of pixels of FIG. 1.

FIG. 6 is a schematic cross-sectional view illustrating an embodiment along line X-X′ of FIG. 5.

FIG. 7 is a schematic diagram illustrating a first area of FIG. 6.

FIG. 8 is a schematic diagram illustrating paths of first light and second light in a first area of FIG. 6.

FIG. 9 is a schematic cross-sectional view illustrating another embodiment along line X-X′ of FIG. 5.

FIG. 10 is a schematic cross-sectional diagram illustrating yet another embodiment along line X-X′ of FIG. 5.

FIG. 11 is a schematic block diagram illustrating an embodiment of a display system.

FIGS. 12 to 15 are schematic perspective views illustrating application examples of the display system of FIG. 11.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

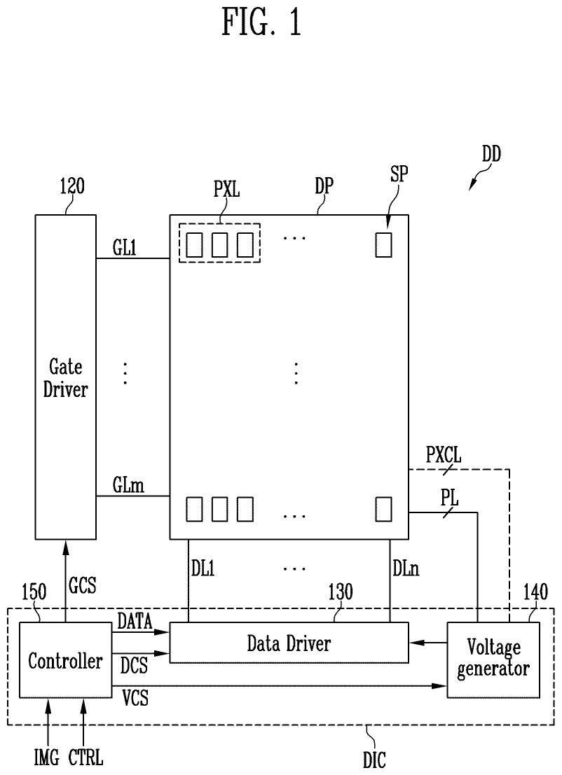

FIG. 1 is a schematic block diagram illustrating an embodiment of a display device.

Referring to FIG. 1, a display device DD may include a display panel DP, a gate driver 120, a data driver 130, a voltage generator 140, and a controller 150.

The display panel DP may include sub-pixels SP. The sub-pixels SP may be connected to the gate driver 120 through first to m^{th} gate lines GL1 to GLm. The sub-pixels SP may be connected to the data driver 130 through first to n^{th} data lines DL1 to DLn.

The sub-pixels SP may generate light of two or more colors. For example, each of the sub-pixels SP may generate light of red, green, blue, cyan, magenta, yellow, etc.

Two or more sub-pixels among the sub-pixels SP may constitute a pixel PXL. For example, the pixel PXL may include three sub-pixels as illustrated in FIG. 1. For example, the pixel PXL may emit light of various colors and various brightnesses according to the combination of light emitted from the sub-pixels included therein.

The gate driver 120 is connected to the sub-pixels SP arranged in the row direction through the first to m^{th} gate lines GL1 to GLm. The gate driver 120 may output gate signals to the first to m^{th} gate lines GL1 to GLm in response to a gate control signal GCS. In embodiments, the gate control signal GCS may include a start signal indicating the start of each frame, a horizontal synchronization signal, and the like.

The gate driver 120 may be disposed on a side (e.g., single side) of the display panel DP. However, embodiments are not limited thereto. For example, the gate driver 120 may be divided into two or more drivers that are physically and/or logically separated, and such drivers may be disposed on the side of the display panel DP and another side of the display panel DP opposite to the side. For example, the gate driver 120 may be disposed around the display panel DP in various forms according to embodiments.

The data driver 130 may be connected to the sub-pixels SP arranged in the column direction through the first to n^{th} data lines DL1 to DLn. The data driver 130 may receive image data DATA and a data control signal DCS from the controller 150. The data driver 130 may operate in response to the data control signal DCS. In embodiments, the data control signal DCS may include a source start signal, a source shift clock, a source output enable signal, and the like.

The data driver 130 may receive voltages from the voltage generator 140. The data driver 130 may apply data signals having grayscale voltages corresponding to the image data DATA to the first to n^{th} data lines DL1 to DLn using the received voltages. In case that a gate signal is applied to each of the first to m^{th} gate lines GL1 to GLm, data signals corresponding to the image data DATA may be applied to the data lines DL1 to DLn. Accordingly, the sub-pixels SP may generate light corresponding to the data signals, and the display panel DP may display an image.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may generate voltages and provide the generated voltages to components of the display device DD, such as the gate driver 120, the data driver 130, and the controller 150. The voltage generator 140 may generate the voltages by receiving an input voltage from the outside of the display device DD and by regulating the received voltage.

The voltage generator 140 may generate a first power voltage and a second power voltage. The generated first and second power voltages may be provided to the sub-pixels SP through power lines PL. In other embodiments, at least one of the first and second power voltages may be provided from the outside of the display device DD.

For example, the voltage generator 140 may provide various voltages and/or signals. For example, the voltage generator 140 may provide one or more initialization voltages applied to the sub-pixels SP. For example, during a sensing operation for sensing electrical characteristics of transistors and/or light-emitting elements of the sub-pixels SP, a predetermined (or selected) reference voltage may be applied to the first to n^{th} data lines DL1 to DLn, and the voltage generator 140 may generate the reference voltage and transmit it to the data driver 130. For example, during a display operation for displaying an image on the display panel DP, common pixel control signals may be applied to the sub-pixels SP, and the voltage generator 140 may generate the pixel control signals. In embodiments, the voltage generator 140 may provide pixel control signals to the sub-pixels SP through pixel control lines PXCL. Although FIG. 1 illustrates that the pixel control lines PXCL are connected between the voltage generator 140 and the display panel DP, embodiments are not limited thereto. For example, the pixel control lines PXCL may be connected between the gate driver 120 and the display panel DP. For example, the pixel control signals may be transmitted from the voltage generator 140 to the pixel control lines PXCL through the gate driver 120.

The controller 150 controls all operations of the display device DD. The controller 150 may receive input image data IMG and a control signal CTRL corresponding thereto from the outside. The controller 150 may provide a gate control signal GCS, a data control signal DCS, and a voltage control signal VCS in response to the control signal CTRL.

The controller 150 may convert the input image data IMG to be suitable for the display device DD or the display panel DP and output image data DATA. In embodiments, the controller 150 may align the input image data IMG to be suitable for sub-pixels SP in a row unit and output the image data DATA.

Two or more components of the data driver 130, the voltage generator 140, and the controller 150 may be mounted on a single integrated circuit. As illustrated in FIG. 1, the data driver 130, the voltage generator 140, and the controller 150 may be included in a driver integrated circuit DIC. For example, the data driver 130, the voltage generator 140, and the controller 150 may be functionally separate components within a single driver integrated circuit DIC. In other embodiments, at least one of the data driver 130, the voltage generator 140, and the controller 150 may be provided as a separate component from the driver integrated circuit DIC.

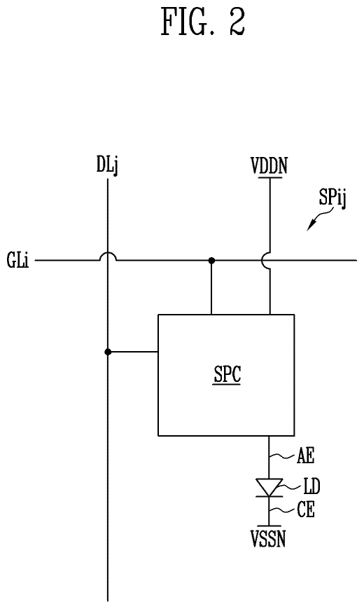

FIG. 2 is a schematic block diagram illustrating an embodiment of any one of sub-pixels of FIG. 1. In FIG. 2, a sub-pixel SPij arranged in an i^{th} row (i is an integer greater than or equal to 1 and less than or equal to m) and a j^{th} column (j is an integer greater than or equal to 1 and less than or equal to n) among the sub-pixels SP of FIG. 1 is illustrated.

Referring to FIG. 2, the sub-pixel SPij may include a sub-pixel circuit SPC and a light-emitting element LD.

The light-emitting element LD may be connected between a first power voltage node VDDN and a second power voltage node VSSN. The first power voltage node VDDN may be connected to one of the power lines PL of FIG. 1 and may receive a first power voltage. The second power voltage node VSSN may be connected to another one of the power lines PL of FIG. 1 and may receive a second power voltage. The first power voltage may have a higher voltage level than the second power voltage.

The light-emitting element LD may be connected between an anode electrode AE and a cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode electrode CE may be connected to the second power voltage node VSSN. The light-emitting element LD may emit light according to a current flowing from the anode electrode AE to the cathode electrode CE.

The sub-pixel circuit SPC may be connected to an i^{th} gate line GLi among the first to m^{th} gate lines GL1 to GLm of FIG. 1, and a j^{th} data line DLj among the first to n^{th} data lines DL1 to DLn of FIG. 1. In response to a gate signal received through the i^{th} gate line GLi, the sub-pixel circuit SPC may control the light-emitting element LD to emit light according to a data signal received through the j^{th} data line DLj. In embodiments, the sub-pixel circuit SPC may be further connected to the pixel control lines PXCL of FIG. 1. For example, the sub-pixel circuit SPC may further control the light-emitting element LD in response to pixel control signals received through the pixel control lines PXCL.

For these operations, the sub-pixel circuit SPC may include circuit elements, for example, transistors and one or more capacitors.

The transistors of the sub-pixel circuit SPC may include P-type transistors and/or N-type transistors. In embodiments, the transistors of the sub-pixel circuit SPC may include a metal oxide silicon field effect transistor (MOSFET). In embodiments, the transistors of the sub-pixel circuit SPC may include an amorphous silicon semiconductor, a monocrystalline silicon semiconductor, a polycrystalline silicon semiconductor, an oxide semiconductor, or the like.

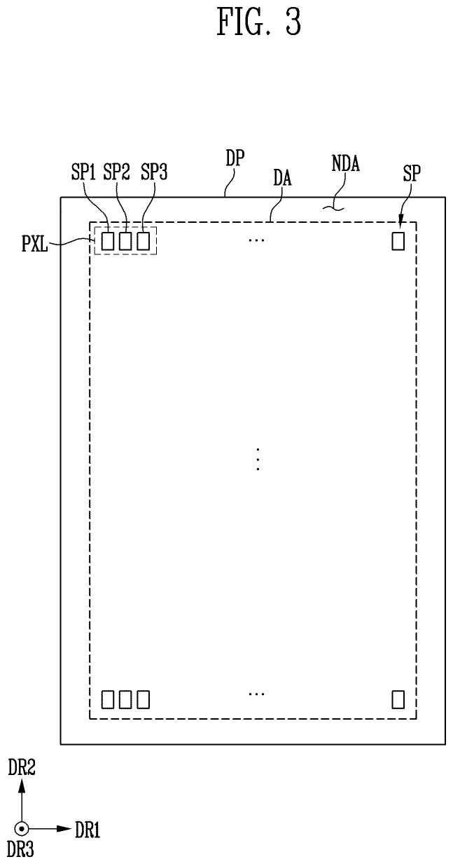

FIG. 3 is a schematic plan view illustrating an embodiment of a display panel of FIG. 1.

Referring to FIG. 3, a display panel DP may include a display area DA and a non-display area NDA. The display panel DP may display an image through the display area DA. The non-display area NDA may be arranged around the display area DA.

The display panel DP may include sub-pixels SP in the display area DA. The sub-pixels SP may be arranged along a first direction DR1 and a second direction DR2 intersecting the first direction DR1. For example, the sub-pixels SP may be arranged in a matrix form along the first direction DR1 and the second direction DR2. As another example, the sub-pixels SP may be arranged in a zigzag form along the first direction DR1 and the second direction DR2. The arrangement of the sub-pixels SP may vary according to the embodiments. The first direction DR1 may be a row direction, and the second direction DR2 may be a column direction.

Among the sub-pixels SP, two or more sub-pixels may constitute a pixel PXL. In FIG. 3, the pixel PXL is illustrated as including three sub-pixels SP1, SP2, and SP3, but embodiments are not limited thereto. For example, the pixel PXL may include two sub-pixels. Hereinafter, for convenience of explanation, it is assumed that the pixel PXL includes first to third sub-pixels SP1, SP2, and SP3.

Each of the first to third sub-pixels SP1, SP2, and SP3 may generate light of one of various colors, such as red, green, blue, cyan, magenta, and yellow. Hereinafter, for clear and concise explanation, it is assumed that the first sub-pixel SP1 generates light of red color, the second sub-pixel SP2 generates light of green color, and the third sub-pixel SP3 generates light of blue color.

Each of the first to third sub-pixels SP1, SP2, and SP3 may include at least one light-emitting element configured to generate light. In embodiments, the light-emitting elements of the first to third sub-pixels SP1, SP2, and SP3 may generate light of the same color. For example, the light-emitting elements of the first to third sub-pixels SP1, SP2, and SP3 may generate light of blue color. In other embodiments, the light-emitting elements of the first to third sub-pixels SP1, SP2, and SP3 may generate light of different colors. For example, the light-emitting elements of the first to third sub-pixels SP1, SP2, and SP3 may generate light of red color, green color, and blue color, respectively.

As the display panel DP, a self-luminous display panel such as an LED display panel that uses micro-scale or nano-scale light-emitting diodes as light-emitting elements, an organic light-emitting display panel (OLED panel) that uses organic light-emitting diodes as light-emitting elements, etc., may be used.

In the non-display area NDA, components for controlling sub-pixels SP may be disposed. Wirings connected to the sub-pixels SP, for example, the first to m^{th} gate lines GL1 to GLm, the first to n^{th} data lines DL1 to DLn, the power lines PL, and the pixel control lines PXCL of FIG. 1, may be disposed in the non-display area NDA.

At least one of the gate driver 120, the data driver 130, the voltage generator 140, and the controller 150 of FIG. 1 may be disposed in the non-display area NDA of the display panel DP. In embodiments, the gate driver 120 may be disposed in the non-display area NDA. For example, the data driver 130, the voltage generator 140, and the controller 150 may be implemented as a driver integrated circuit DIC of FIG. 1 that is separate from the display panel DP, and the driver integrated circuit DIC may be connected to wirings disposed in the non-display area NDA. In other embodiments, the gate driver 120 may be implemented as a single integrated circuit that is separate from the display panel DP together with the data driver 130, the voltage generator 140, and the controller 150.

In embodiments, the display area DA may have various shapes. The display area DA may have a shape of a closed loop including straight and/or curved sides. For example, the display area DA may have shapes such as a polygon, a circle, a semicircle, an ellipse, etc.

In embodiments, the display panel DP may have a flat display surface. In other embodiments, the display panel DP may have an at least partially rounded display surface. In embodiments, the display panel DP may be bendable, foldable, or rollable. In such cases, the display panel DP and/or the substrate of the display panel DP may include materials having flexible properties.

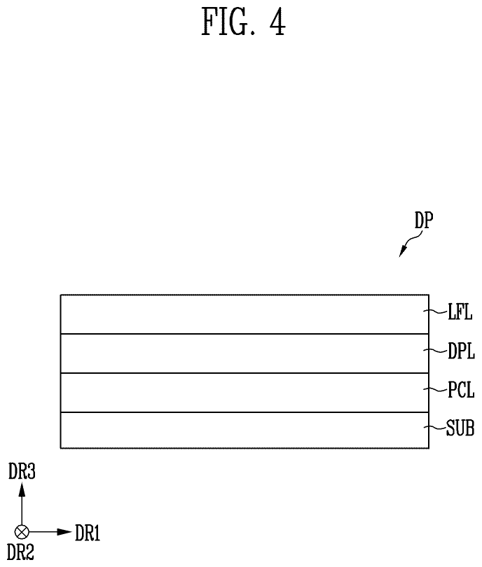

FIG. 4 is a schematic cross-sectional view illustrating an embodiment of the display panel of FIG. 3.

Referring to FIG. 3, the display panel DP may include a substrate SUB, and a pixel circuit layer PCL, a display element layer DPL, and a light functional layer LFL that are sequentially laminated in a third direction DR3 intersecting the first and second directions DR1 and DR2 on the substrate SUB.

The substrate SUB may be made of an insulating material, such as glass or resin. For example, the substrate SUB may include a glass substrate. As another example, the substrate SUB may include a polyimide (PI) substrate. As another example, the substrate SUB may include a silicon wafer substrate formed using a semiconductor process.

In embodiments, the substrate SUB may be formed of a flexible material such that it may be bent or folded, and may have a single-layer structure or a multi-layer structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, cellulose acetate propionate. However, embodiments are not limited thereto.

The pixel circuit layer PCL may be disposed on the substrate SUB. The pixel circuit layer PCL may include insulating layers and semiconductor patterns and conductive patterns disposed between the insulating layers. The conductive patterns of the pixel circuit layer PCL may function as circuit elements, wirings, etc.

The circuit elements of the pixel circuit layer PCL may include sub-pixel circuits (SPC, see FIG. 2) of each of the sub-pixels SP of FIG. 3. For example, the circuit elements of the pixel circuit layer PCL may be provided as transistors and one or more capacitors of the sub-pixel circuit SPC.

The wirings of the pixel circuit layer PCL may include wirings connected to the sub-pixels SP. The wirings of the pixel circuit layer PCL may include various signal lines and/or voltage lines required to drive the display element layer DPL.

The display element layer DPL may be disposed on the pixel circuit layer PCL. The display element layer DPL may include light-emitting elements of the sub-pixels SP.

The light functional layer LFL may be disposed on the display element layer DPL. The light functional layer LFL may include light conversion patterns having color conversion particles and/or scattering particles. For example, the color conversion particles may include quantum dots. The quantum dots may change the wavelength (or color) of light emitted from the display element layer DPL. The light functional layer LFL may further include light scattering patterns having scattering particles. In embodiments, the light conversion patterns and the light scattering patterns may be omitted.

The light functional layer LFL may include a lens array LS and a reflective part RL. For example, the light functional layer LFL may include a lens array LS disposed to correspond to each of the sub-pixels SP. For example, the light functional layer LFL may include the reflective part RL that reflects at least a portion of the light emitted from the light-emitting elements LD.

A window for protecting an exposed surface (or upper surface) of the display panel DP may be provided on the light functional layer LFL. The window may protect the display panel DP from external impact. The window may be coupled to the light functional layer LFL through an optically transparent adhesive (or bonding) member. The window may have a multilayer structure selected from a glass substrate, a plastic film, and a plastic substrate. This multilayer structure may be formed through a continuous process or an adhesive process using an adhesive layer. All or a portion of the window may be flexible.

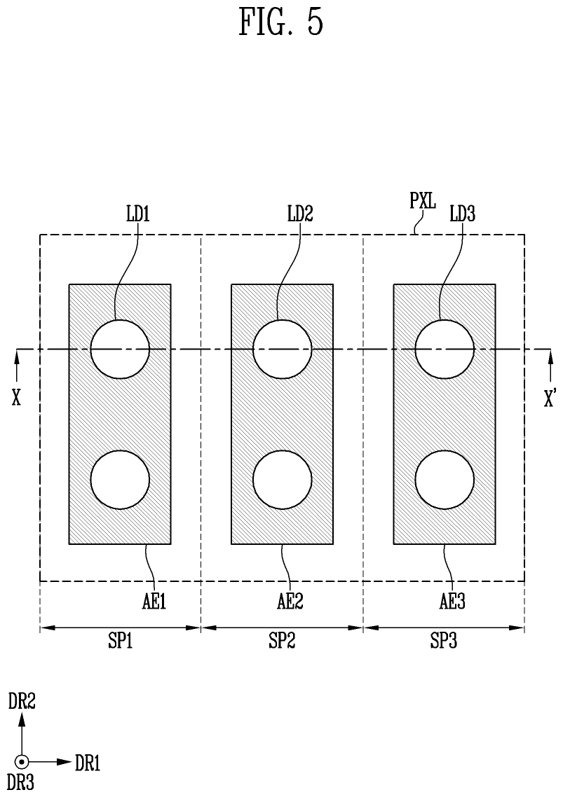

FIG. 5 is a schematic plan view illustrating an embodiment of any one of pixels of FIG. 1.

Referring to FIG. 5, a pixel PXL may include first to third sub-pixels SP1, SP2, and SP3. The first to third sub-pixels SP1, SP2, and SP3 may be arranged in a first direction DR1. However, the arrangement of the pixels PXL is not limited thereto and may vary according to embodiments. For example, the first to third sub-pixels SP1, SP2, and SP3 may be arranged in a zigzag manner.

First to third anode electrodes AE1, AE2, and AE3 may be respectively disposed in the first to third sub-pixels SP1, SP2, and SP3. The first anode electrode AE1 may be provided as an anode electrode (AE, see FIG. 2) included in a sub-pixel circuit (SPC, see FIG. 2) of the first sub-pixel SP1. The second anode electrode AE2 may be provided as an anode electrode AE included in a sub-pixel circuit SPC of the second sub-pixel SP2. The third anode electrode AE3 may be provided as an anode electrode AE included in a sub-pixel circuit SPC of the third sub-pixel SP3.

On the first to third anode electrodes AE1, AE2, and AE3, one or more first light-emitting elements LD1, one or more second light-emitting elements LD2, and one or more third light-emitting elements LD3 may be disposed. The first light-emitting elements LD1 may be connected to the first anode electrode AE1. The second light-emitting elements LD2 may be connected to the second anode electrode AE2. The third light-emitting elements LD3 may be connected to the third anode electrode AE3. In case that light-emitting elements are provided in each sub-pixel, each anode electrode may have a shape extending in a specific direction, such as a second direction DR2, and the light-emitting elements connected thereto may be arranged in the same direction.

The first light-emitting elements LD1 may be provided as the light-emitting elements LD of FIG. 2 included in the first sub-pixel SP1. The second light-emitting elements LD2 may be provided as the light-emitting elements LD of FIG. 2 included in the second sub-pixel SP2. The third light-emitting element LD3 may be provided as the light-emitting element LD of FIG. 2 included in the third sub-pixel SP3. In case that light-emitting elements are provided in one sub-pixel, the light-emitting elements may be connected in parallel between the anode electrode and the cathode electrode to be provided as the light-emitting element LD of FIG. 2.

The first light-emitting elements LD1, the second light-emitting elements LD2, and the third light-emitting elements LD3 may be inorganic light-emitting diodes including inorganic light-emitting materials. However, embodiments are not limited thereto, and for example, organic light-emitting diodes may be used.

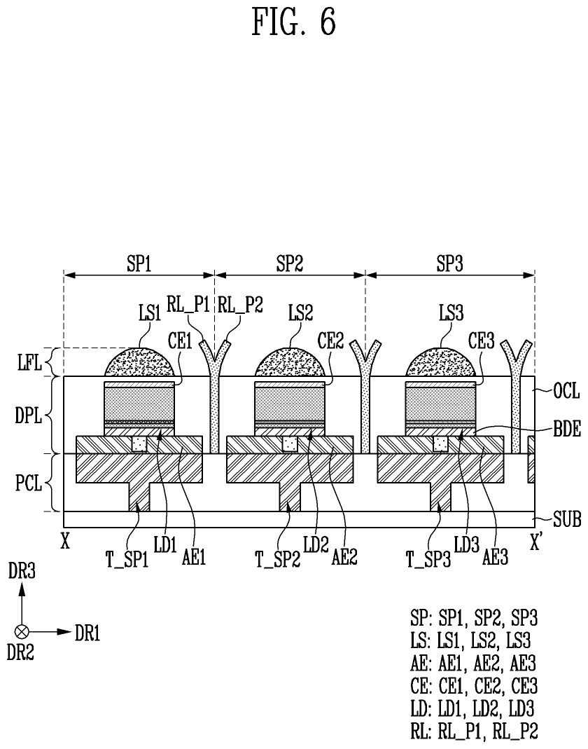

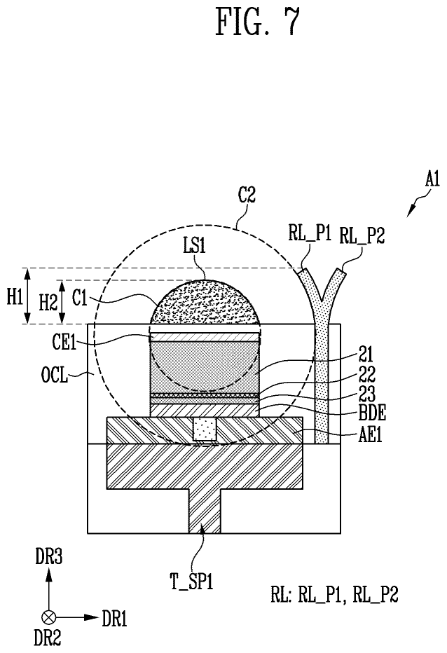

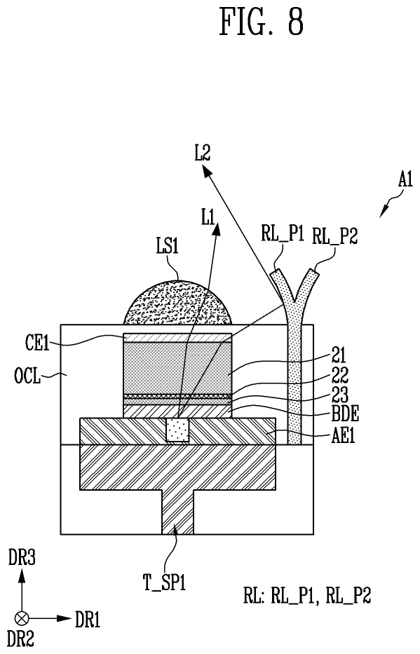

FIG. 6 is a schematic cross-sectional view illustrating an embodiment along line X-X′ of FIG. 5. FIG. 7 is a diagram illustrating a first area of FIG. 6. FIG. 8 is a diagram illustrating paths of first light and second light in a first area of FIG. 6.

Hereinafter, for convenience of explanation, the first sub-pixel SP1 (or a first area A1) will be described, but the second sub-pixel SP2 and the third sub-pixel SP3 may also be described in the same manner.

Referring to FIGS. 5 and 6, a pixel circuit layer PCL, a display element layer DPL, and a light functional layer LFL may be sequentially disposed on a substrate SUB.

The pixel circuit layer PCL may include insulating layers, semiconductor patterns, and conductive patterns laminated on the substrate SUB. The insulating layers may include one or more interlayer insulating layers and one or more passivation layers. The semiconductor patterns and the conductive patterns may be located between the insulating layers. The conductive patterns may include at least one material of copper (Cu), molybdenum (Mo), tungsten (W), aluminum neodymium (AlNd), titanium (Ti), aluminum (Al), and silver (Ag).

As described with reference to FIG. 2, the sub-pixel circuit (SPC, see FIG. 2) of each of the first to third sub-pixels SP1, SP2, and SP3 may include transistors and one or more capacitors. The semiconductor patterns and the conductive patterns of the pixel circuit layer PCL may function as the transistors and capacitors of the sub-pixel circuit SPC. For example, the conductive patterns of the pixel circuit layer PCL may further function as wirings, for example, the first to m^{th} gate lines GL1 to GLm, the first to n^{th} data lines DL1 to DLn, the power lines PL, and the pixel control lines PXCL of FIG. 1.

On the substrate SUB, first to third transistors T_SP1, T_SP2, and T_SP3 corresponding to the first to third sub-pixels SP1, SP2, and SP3, respectively, may be disposed. The first transistor T_SP1 may be any one of the transistors of the sub-pixel circuit SPC included in the first sub-pixel SP1. The second transistor T_SP1 may be any one of the transistors of the sub-pixel circuit SPC included in the second sub-pixel SP2. The third transistor (T_SP3) may be any one of the transistors of the sub-pixel circuit SPC included in the third sub-pixel SP3. Each of the first to third transistors T_SP1, T_SP2, and T_SP3 may be understood as a transistor connected to the anode electrode among the transistors of the corresponding sub-pixel.

The first transistor T_SP1 may include a semiconductor pattern and a gate electrode, a first terminal, and a second terminal. For example, among the electrodes, the first terminal may be a source electrode, and the second terminal may be a drain electrode.

The first transistor T_SP1 may be composed of a complementary metal-oxide semiconductor (CMOS). For example, the first transistor T_SP1 may include an n-type transistor and a p-type transistor. For example, both the n-type transistor and the p-type transistor may be metal-oxide-semiconductor field-effect transistors.

For the semiconductor pattern, a semiconductor pattern including any one of various types of semiconductors may include, for example, any one of an amorphous silicon semiconductor, a monocrystalline silicon semiconductor, a polycrystalline silicon semiconductor, a low temperature poly silicon semiconductor, and an oxide semiconductor.

The gate electrode may overlap a channel area of the semiconductor pattern. In embodiments, the gate electrode GE may be provided as a single layer including at least one material of copper (Cu), molybdenum (Mo), tungsten (W), aluminum neodymium (AlNd), titanium (Ti), aluminum (Al), and silver (Ag). In embodiments, the gate electrode GE may be provided as a multilayer including at least one material of low-resistance materials such as molybdenum (Mo), titanium (Ti), copper (Cu), aluminum (Al), and silver (Ag).

The first and second terminals may contact the semiconductor pattern. Each of the first and second terminals may include at least one material of copper (Cu), molybdenum (Mo), tungsten (W), aluminum neodymium (AlNd), titanium (Ti), aluminum (Al), and silver (Ag).

In embodiments, the first transistor T_SP1 may be formed of a low-temperature polysilicon transistor. However, embodiments are not limited thereto. For example, the first transistor T_SP1 may also be formed of an oxide semiconductor transistor. In embodiments, the sub-pixel circuit of each sub-pixel may include transistors of different types. For example, the first transistor T_SP1 may be formed of a low-temperature polysilicon transistor, and the other transistor of the first sub-pixel SP1 may be formed of an oxide semiconductor transistor.

Each of the second and third transistors T_SP2 and T_SP3 may be formed (or configured) similarly to the first transistor T_SP1. Hereinafter, redundant descriptions are omitted.

The display element layer DPL may include first to third anode electrodes AE1, AE2, and AE3, first to third light-emitting elements LD1, LD2, and LD3, an overcoat layer OCL, a cathode electrode CE, and a capping layer.

On the pixel circuit layer PCL, the first to third anode electrodes AE1, AE2, and AE3 may be disposed on the first to third sub-pixels SP1, SP2, and SP3, respectively. The first anode electrode AE1 may consist of metal. Accordingly, it may be electrically connected to the first transistor T_SP1. For example, the second and third anode electrodes AE2 and AE3 may be electrically connected to the second to third transistors T_SP2 and T_SP3, respectively.

A reflective part RL may be disposed between the first to third anode electrodes AE1, AE2, and AE3. The reflective part RL may be provided as a pixel definition film that defines areas where the first to third light-emitting elements LD1, LD2, and LD3 are located.

The first to third light-emitting elements LD1, LD2, and LD3 may be disposed on the first to third anode electrodes AE1, AE2, and AE3, respectively. The first to third light-emitting elements LD1, LD2, and LD3 may be bonded and coupled to the first to third anode electrodes AE1, AE2, and AE3, respectively.

Referring to FIGS. 6, 7, and 8, the first light-emitting element LD1 may include a bonding electrode BDE, a first semiconductor layer 21, an active layer 22, and a second semiconductor layer 23. The first light-emitting element LD1 may be implemented as a vertical light-emitting laminate in which the bonding electrode BDE, the second semiconductor layer 23, the active layer 22, and the first semiconductor layer 21 may be sequentially laminated along a third direction DR3.

The first semiconductor layer 21 may provide electrons. The first semiconductor layer 21 may include, for example, at least one n-type semiconductor layer. For example, the first semiconductor layer 21 may include any one of a semiconductor material of gallium nitride (GaN), aluminum gallium nitride (AlGaN), indium gallium nitride (InGaN), aluminum nitride (AlN), and indium nitride (InN), and may be an n-type semiconductor layer doped with a first conductive dopant (or n-type dopant) such as silicon (Si), germanium (Ge), tin (Sn), etc. However, the material constituting the first semiconductor layer 21 is not limited thereto, and various other materials may constitute the first semiconductor layer 21. In an embodiment, the first semiconductor layer 21 may include a gallium nitride (GaN) semiconductor material doped with the first conductive dopant (or n-type dopant).

The active layer 22 may be disposed on the first semiconductor layer 21 and may be an area where electrons and holes recombine. As electrons and holes recombine in the active layer 22, transitioning to a lower energy level, light with a corresponding wavelength may be generated. The active layer 22 may be formed as a single or multiple quantum well structure. In case that the active layer 22 is formed as a multiple quantum well structure, units including a barrier layer, a strain reinforcing layer, and a well layer may be repeatedly laminated to form the active layer 22. However, embodiments of the active layer 22 are not limited thereto.

The second semiconductor layer 23 may be disposed on the active layer 22 and provides holes to the active layer 22. The second semiconductor layer 23 may include a semiconductor layer of a different type from the first semiconductor layer 21. For example, the second semiconductor layer 23 may include at least one p-type semiconductor layer. For example, the second semiconductor layer 23 may include at least one semiconductor material of gallium nitride (GaN), aluminum gallium nitride (AlGaN), indium gallium nitride (InGaN), aluminum nitride (AlN), and indium nitride (InN), and may be a p-type semiconductor layer doped with a second conductive dopant (or p-type dopant) such as magnesium (Mg), zinc (Zn), calcium (Ca), strontium (Sr), barium (Ba), etc. However, the material constituting the second semiconductor layer 23 is not limited thereto, and various other materials may constitute the second semiconductor layer 23. In an embodiment, the second semiconductor layer 23 may include a gallium nitride (GaN) semiconductor material doped with the second conductive dopant (or p-type dopant).

The bonding electrode BDE may be electrically connected to the second semiconductor layer 23. The bonding electrode BDE may include a eutectic metal.

The first light-emitting element LD1 may further include an insulating film covering an outer surface of the vertical light-emitting laminate. The insulating film may prevent an electrical short circuit that may occur in case that the active layer 22 comes into contact with a conductive material other than the first and second semiconductor layers 21, 23.

A lower surface of the bonding electrode BDE may be connected to the first anode electrode AE1. An upper surface (or an upper surface of the insulating film) of the first light-emitting element LD1 may be connected to the cathode electrode CE. Accordingly, the first light-emitting element LD1 may be electrically connected between the first anode electrode AE1 and the cathode electrode CE.

Each of the second and third light-emitting elements LD2 and LD3 may be formed (or configured) similarly to the first light-emitting element LD1. Hereinafter, redundant descriptions are omitted.

The display element layer DPL may include an overcoat layer OCL. The overcoat layer OCL may fix the first to third light-emitting elements LD1, LD2, and LD3 bonded to the first to third anode electrodes AE1, AE2, and AE3 so as not to move. For example, the overcoat layer OCL may protect components disposed thereunder from foreign substances such as dust, moisture, and the like.

The overcoat layer OCL may include a dielectric material. According to an embodiment, the overcoat layer OCL may include at least one of an inorganic insulating layer and an organic insulating layer. For example, the overcoat layer OCL may include epoxy, but embodiments are not limited thereto.

Cathode electrodes CE may be disposed on the first to third light-emitting elements LD1, LD2, and LD3. For example, the first to third cathode electrodes CE1, CE2, and CE3 may be disposed on the first to third light-emitting elements LD1, LD2, and LD3, respectively. However, embodiments are not limited thereto. For example, the cathode electrode CE may be disposed entirely (or overall) on the first to third light-emitting elements LD1, LD2, and LD3 and the overcoat layer OCL.

The cathode electrodes CE may contact the first semiconductor layer 21 of each of the first to third light-emitting elements LD1, LD2, and LD3. The cathode electrode CE may be electrically connected to the second power voltage node VSSN of FIG. 2. The second power voltage applied to the second power voltage node VSSN may be transmitted to the first to third light-emitting elements LD1, LD2, and LD3 through the cathode electrode CE.

The cathode electrode CE may be formed (or configured) to be substantially transparent or translucent so as to satisfy a predetermined (or selected) light transmittance. In embodiments, the cathode electrode CE may include at least one of various transparent conductive materials, such as indium tin oxide (ITO), indium zinc oxide (IZO), zinc oxide (ZnO), indium gallium zinc oxide (IGZO), and indium tin zinc oxide (ITZO). However, the material of the cathode electrode CE is not limited thereto.

Although not shown in FIGS. 6 to 8, a capping layer may be disposed on the cathode electrode CE. The capping layer may protect components, such as the cathode electrode CE, the first to third light-emitting elements LD1, LD2, and LD3, and the like, from external moisture, humidity, and the like. The capping layer may include at least one of a metal oxide, such as silicon nitride (SiNx), silicon oxide (SiOx), silicon oxynitride (SiOxNy), and aluminum oxide (AlOx).

The light functional layer LFL may be disposed on the capping layer. The light functional layer LFL may include a lens array LS and a reflective part RL.

The lens array LS may include first to third lenses LS1, LS2, and LS3 corresponding to the first to third sub-pixels SP1, SP2, and SP3. For example, the first lens LS1 may be disposed on the first sub-pixel SP1.

The lens array LS may be implemented in the form of a lens array such as a micro lens array. However, embodiments are not limited thereto.

Referring to FIGS. 6 and 8, the first lens LS1 may refract at least a portion of the light output from the first light-emitting element LD1. For example, the first light L1 output from the first light-emitting element LD1 may be refracted by the first lens LS1. For example, the first light L1 may be refracted in a first direction DR1 at the cathode electrode CE1. For example, in case that the first lens LS1 is not disposed, the first light L1 may go straight in an unintended direction (for example, in the first direction DR1). For example, the first lens LS1 may refract the first light L1 in a direction opposite to the first direction DR1. Accordingly, the light output from the first light-emitting element LD1 and the light output from the second light-emitting element LD2 may be prevented from being unintendedly mixed, and the light emission efficiency of the display panel (DP, see FIG. 3) may be increased.

The reflective part RL may reflect at least a portion of the light output from the first light-emitting element LD1. For example, the reflective part RL may reflect light that is not refracted by the first lens LS1 among light output from the first light-emitting element LD1. The second light L2 may be refracted in the first direction DR1 by the cathode electrode CE1. In case that the reflective part RL is not disposed, the second light L2 may go straight in an unintended direction (for example, in the first direction DR1). For example, the reflective part RL may reflect the second light L2 in a direction opposite to the first direction DR1. Accordingly, the light output from the first light-emitting element LD1 and the light output from the second light-emitting element LD2 may be prevented from being unintentionally mixed, and the light emission efficiency of the display panel DP may be increased.

The reflective part RL may include one end including a first reflective part RL_P1 and a second reflective part RL_P2. For example, one end of the reflective part RL may include the first reflective part RL_P1 that is bent in a direction opposite to the first direction DR1 and the second reflective part RL_P2 that is bent in the first direction DR1. The first reflective part RL_P1 and the second reflective part RL_P2 may have symmetrical shapes with respect to the third direction DR3.

The first reflective part RL_P1 may reflect light output from the first light-emitting element LD1 in a direction opposite to the first direction DR1. The second reflective part RL_P2 may reflect light output from the second light-emitting element LD2 in the first direction DR1.

The reflective part RL may have a refractive index lower than a refractive index of air. Accordingly, at least some of the light incident on the reflective part RL may be totally reflected. For example, the reflective part RL may be formed (or configured) to refract or totally reflect the light according to the incident angle of the light.

The reflective part RL may include a material suitable for reflecting light. The reflective layer RFL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected therefrom. However, embodiments are not limited thereto.

According to an embodiment, the light reflection ratio of the reflective part RL may be about 90% or more. For example, about 90% or more of the lights incident on the reflective part RL may be reflected in a direction opposite to the first direction DR1. However, this is an example, and embodiments are not limited thereto.

Referring to FIGS. 6 and 7, in a cross-section, a height of the reflective part RL in the third direction DR3 from the upper surface of the display element layer DPL may be a first height H1. In a cross-section, a height of the first lens LS1 in the third direction DR3 from the upper surface of the display element layer DPL may be a second height H2. For example, the first height H1 may be greater than the second height H2. In a cross-section, the reflective part RL may be extended longer in the third direction DR3 than the first lens LS1. Accordingly, light output from the first light-emitting element LD1 may be effectively reflected.

Referring to FIG. 7, the first lens LS1 may have a first curvature corresponding to a first circle C1. For example, the first circle C1 may have the first curvature, and a convex shape of the first lens LS1 may overlap the first circle C1 and have the first curvature.

The reflective part RL may have a predetermined (or selected) curvature. For example, the first reflective part RL_P1 may have a second curvature that is bent in the opposite direction to the first direction DR1. For example, the first reflective part RL_P1 may correspond to a second circle C2. For example, the second circle C2 may have the second curvature, and the bent shape of the first reflective part RL_P1 may overlap the second circle C2 and have the second curvature.

The first curvature and the second curvature may be the same as each other. For example, the degrees of bending of the first lens LS1 and the first reflective part RL_P1 may be substantially the same as each other. According to an embodiment, the size of the first curvature and the size of the second curvature may be proportional. For example, the first curvature and the second curvature may have a proportional relationship of 1:2. However, this is an example, and embodiments are not limited thereto.

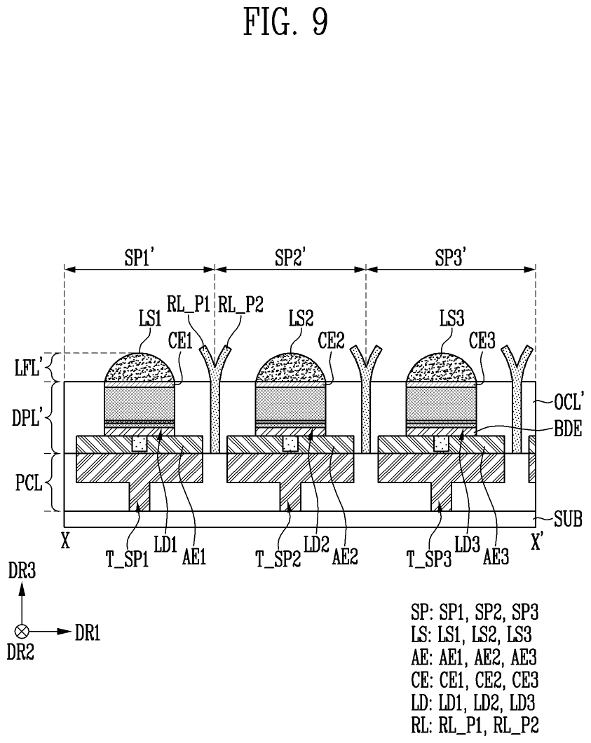

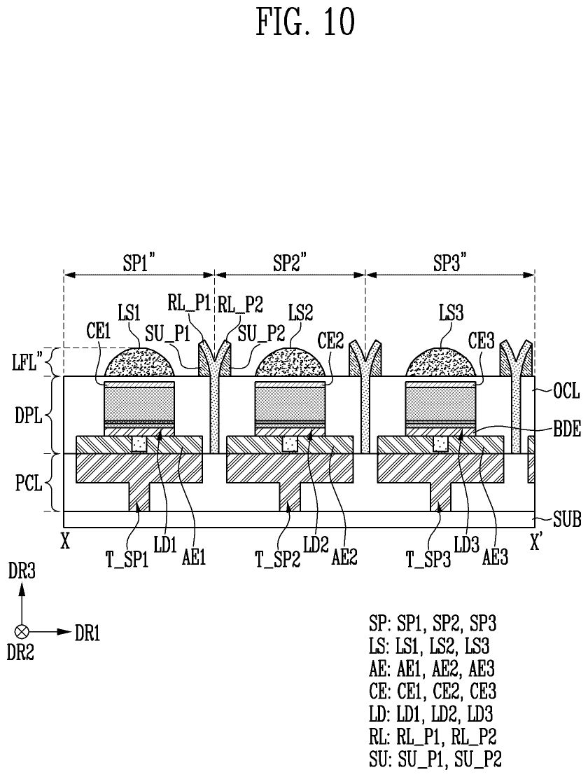

FIG. 9 is a schematic cross-sectional view illustrating another embodiment along line X-X′ of FIG. 5. FIG. 10 is a schematic cross-sectional diagram illustrating yet another embodiment along line X-X′ of FIG. 5.

Referring to FIG. 9, a pixel circuit layer PCL, a display element layer DPL′, and a light functional layer LFL′ may be sequentially disposed on a substrate SUB. The substrate SUB and the pixel circuit layer PCL of FIG. 9 may be described in the same manner as the substrate SUB and the pixel circuit layer PCL of FIG. 5. Hereinafter, redundant descriptions will be omitted.

The display element layer DPL′ may include first to third light-emitting elements LD1, LD2, and LD3 and an overcoat layer OCL′. For example, the first to third light-emitting elements LD1, LD2, and LD3 of FIG. 9 may be described in the same manner as the first to third light-emitting elements LD1, LD2, and LD3 of FIG. 5. Hereinafter, redundant descriptions will be omitted.

On the pixel circuit layer PCL, first to third anode electrodes AE1, AE2, and AE3 may be disposed on first to third sub-pixels SP1′, SP2′, and SP3′, respectively.

The overcoat layer OCL′ may fix the first to third light-emitting elements LD1, LD2, and LD3 bonded to the first to third anode electrodes AE1, AE2, and AE3 so as not to move. For example, the overcoat layer OCL′ may protect components disposed thereunder from foreign substances such as dust and moisture.

Cathode electrodes CE may be disposed on the light-emitting elements LD. For example, first to third cathode electrodes CE1, CE2, and CE3 may be disposed on the first to third light-emitting elements LD1, LD2, and LD3, respectively.

According to an embodiment, the cathode electrodes CE may be disposed on the back surface of the light functional layer LFL′. For example, a lens array LS may be disposed (e.g., directly disposed) on the cathode electrodes CE. For example, first to third lenses LS1, LS2, and LS3 may be disposed (e.g., directly disposed) on the upper surfaces of the first to third cathode electrodes CE1, CE2, and CE3.

Referring to FIG. 10, a pixel circuit layer PCL, a display element layer DPL, and a light functional layer LFL″ can be sequentially disposed on a substrate SUB. The substrate SUB, the pixel circuit layer PCL, and the display element layer DPL of FIG. 10 may be described similarly to the substrate SUB, the pixel circuit layer PCL, and the display element layer DPL of FIG. 5. Hereinafter, redundant descriptions will be omitted.

On the pixel circuit layer PCL, first to third anode electrodes AE1, AE2, and AE3 may be respectively disposed on first to third sub-pixels SP1″, SP2″, and SP3″.

A light functional layer LFL″ may include a lens array LS, a reflective part RL, and a support part SU. The lens array LS and the reflective part RL of FIG. 10 may be described in the same manner as the lens array LS and the reflective part RL of FIG. 5. Hereinafter, redundant descriptions will be omitted.

The support part SU may be formed (or configured) to support the reflective part RL. For example, the support part SU may include a first support part SU_P1 and a second support part SU_P2. For example, the first support part SU_P1 may support a first reflective part RL_P1 in a third direction DR3. The second support part SU_P2 may support a second reflective part RL_P2 in the third direction DR3.

The support part SU may be a material having light transparency. For example, the support part SU may be formed (e.g., configured) to be substantially transparent or translucent to satisfy a predetermined (or selected) light transmittance. According to an embodiment, the support part SU may reflect at least some of the light incident on the support part SU.

The support part SU may include an inorganic material and/or an organic material. For example, the support part SU may include at least one of a metal oxide such as silicon oxide (SiOx), silicon nitride (SiNx), silicon oxynitride (SiOxNy), or aluminum oxide (AlOx). For example, the support part SU may include at least one of, for example, an acrylic resin, an epoxy resin, a phenol resin, a polyamide resin, a polyimide resin, an unsaturated polyester resin, a poly-phenylene ether resin, a poly-phenylene sulfide resin, and a benzocyclobutene resin.

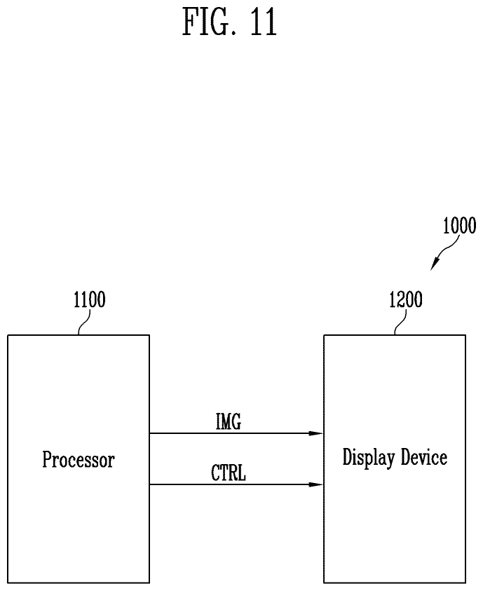

FIG. 11 is a schematic block diagram illustrating an embodiment of a display system.

Referring to FIG. 11, a display system 1000 may include a processor 1100 and a display device 1200.

The processor 1100 may perform various tasks and calculations. In embodiments, the processor 1100 may include an application processor, a graphic processor, a microprocessor, a central processing unit (CPU), etc. The processor 1100 may be connected to other components of the display system 1000 through a bus system and control them.

The processor 1100 may transmit image data IMG and a control signal CTRL to the display device 1200. The display device 1200 may display an image based on the image data IMG and the control signal CTRL. The display device 1200 may be formed (or configured) similarly to the display device DD described with reference to FIG. 1. For example, the image data IMG and the control signal CTRL may be provided as the input image data IMG and the control signal CTRL of FIG. 1, respectively.

The display system 1000 may include a computing system that provides an image display function, such as a smart watch, a mobile phone, a smart phone, a portable computer, a tablet personal computer (PC), a watch phone, an automotive display, smart glasses, a portable multimedia player (PMP), a navigation, an ultra mobile personal computer (UMPC), etc. For example, the display system 1000 may include at least one of a head mounted display (HMD), a virtual reality (VR) device, a mixed reality (MR) device, and an augmented reality (AR) device.

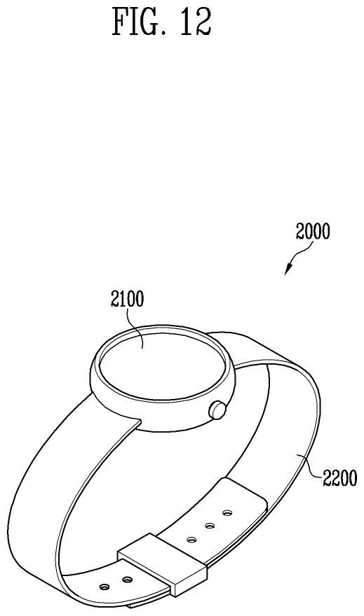

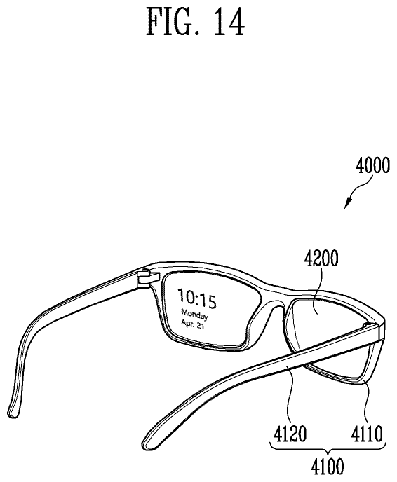

FIGS. 12 to 15 are schematic perspective views showing application examples of the display system of FIG. 11.

Referring to FIG. 12, the display system 1000 of FIG. 11 may be applied to a smart watch 2000 including a display part 2100 and a strap part 2200.

The smart watch 2000 may be a wearable electronic device. For example, the smart watch 2000 may have a structure in which the strap part 2200 is worn on a user's wrist. Here, the display part 2100 may be applied with the display system 1000 and/or the display device 1200, so that image data including time information may be provided to the user.

Referring to FIG. 12, the display system 1000 of FIG. 11 may be applied to an automotive display system 3000. Here, the automotive display system 3000 may include a computing system that is installed inside and/or outside a vehicle and provides image data.

For example, the display system 1000 and/or the display device 1200 may be applied to at least one of an infotainment panel 3100, a cluster 3200, a co-driver display 3300, a head-up display 3400, a side mirror display 3500, and a rear seat display 3600 provided in a vehicle.

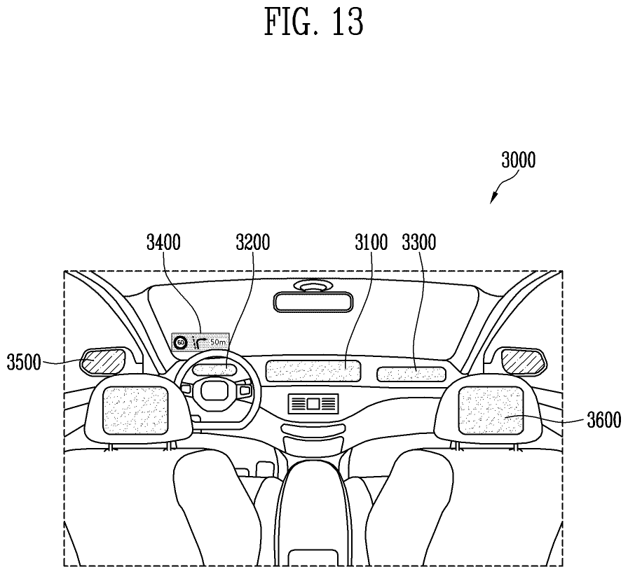

Referring to FIG. 13, the display system 1000 of FIG. 11 may be applied to smart glasses 4000. The smart glasses 4000 may be a wearable electronic device that may be worn on a user's head. For example, the smart glasses 4000 may be a wearable device for augmented reality.

The smart glasses 4000 may include a frame 4100 and a lens part 4200. The frame 4100 may include a housing 4110 that supports the lens part 4200 and a leg part 4120 for the user to wear. The leg part 4120 may be connected to the housing 4110 via a hinge and may be folded or unfolded relative to the housing 4110.

A battery, a touch pad, a microphone, a camera, etc., may be built into the frame 4100. For example, a projector that outputs light, a processor that controls an optical signal, etc., may be built into the frame 4100.

The lens part 4200 may include an optical member that transmits light or reflects light. For example, the lens part 4200 may include glass, a transparent synthetic resin, etc.

To allow the user's eyes to recognize visual information, the lens part 4200 may reflect an image by an optical signal transmitted from the projector of the frame 4100 through the rear surface of the lens part 4200 (e.g., the surface of a direction facing the user's eyes). For example, the user may recognize visual information such as the time and date displayed on the lens part 4200. For example, the projector and/or the lens part 4200 may be a type of display device. The display device 1200 may be applied to the projector and/or lens part 4200.

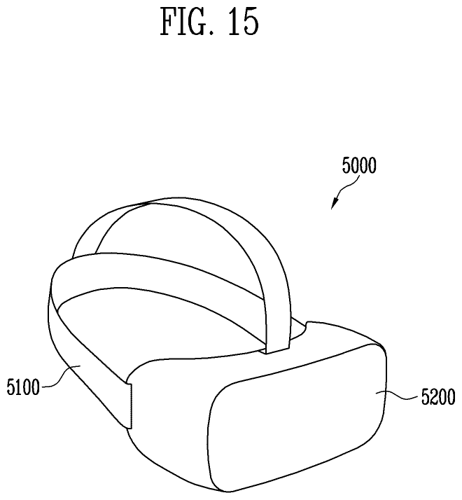

Referring to FIG. 15, the display system 1000 of FIG. 1 may be applied to a head-mounted display device 5000.

The head-mounted display device 5000 may be a wearable electronic device that may be worn on a user's head. For example, the head-mounted display device 5000 may be a wearable device for virtual reality or mixed reality. For example, a display panel (DP, see FIG. 6) tested by a display system (1000, see FIG. 11) may be used in the head-mounted display device 5000.

The head-mounted display device 5000 may include a head-mounted band 5100 and a display device storage case 5200. The head-mounted band 5100 may be connected to the display device storage case 5200. The head-mounted band 5100 may include a horizontal band and/or a vertical band for securing the head-mounted display device 5000 to the user's head. The horizontal band may be formed (or configured) to surround the side of the user's head, and the vertical band may be formed (or configured) to surround the upper part of the user's head. However, embodiments are not limited thereto. For example, the head-mounted band 5100 may be implemented in the form of a glasses frame, a helmet, etc. The display device storage case 5200 may store the display device (DD, see FIG. 1). FIG. 15 illustrates an example, and embodiments are not limited thereto. For example, the display device (DD, see FIG. 1) may be applied to a smart watch or an automotive display system, etc.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a substrate;
a pixel circuit layer disposed on the substrate;
a display element layer disposed on the pixel circuit layer and comprising a first light-emitting element and a second light-emitting element different from the first light-emitting element;
a reflective part disposed between the first light-emitting element and the second light-emitting element; and
a lens array comprising a first lens disposed on the first light-emitting element and a second lens disposed on the second light-emitting element,
wherein an end portion of the reflective part comprises:
a first reflective part, and
a second reflective part extending symmetrically with respect to the first reflective part.

2. The display device of claim 1, wherein
the first lens has a convex shape having a first curvature, and
the first reflective part has a bent shape having a second curvature so as to be adjacent to the first lens.

3. The display device of claim 2, wherein a size of the first curvature and a size of the second curvature are same as each other.

4. The display device of claim 2, wherein a size of the first curvature and a size of the second curvature are proportional.

5. The display device of claim 1, wherein the reflective part is in contact with an upper surface of the pixel circuit layer.

6. The display device of claim 1, wherein the display element layer comprises an overcoat layer disposed on the first light-emitting element and the second light-emitting element.

7. The display device of claim 6, wherein the overcoat layer comprises a dielectric.

8. The display device of claim 6, wherein the reflective part extends in a direction and penetrates the overcoat layer.

9. The display device of claim 6, wherein the lens array is disposed on the overcoat layer.

10. The display device of claim 1, wherein
each of the first light-emitting element and the second light-emitting element comprises a first electrode disposed on the pixel circuit layer and a second electrode overlapping the first electrode, and
the lens array is directly disposed on a third electrode.

11. The display device of claim 1, wherein the end portion of the reflective part extends higher than a height of the lens array in cross-section.

12. The display device of claim 1, further comprising a support part that supports the first reflective part and the second reflective part of the reflective part.

13. The display device of claim 12, wherein the support part has light transparency.

14. The display device of claim 1, wherein
the pixel circuit layer comprises one or more transistors, and
the one or more transistors comprise a complementary metal-oxide-semiconductor.

15. The display device of claim 1, wherein the first light-emitting element and the second light-emitting element are micro light emitting diodes (LED).

16. A display system comprising:
a processor that provides input image data to a display device; and
the display device that displays an image based on the input image data, wherein
the display device comprises:
a substrate;
a pixel circuit layer disposed on the substrate;
a display element layer disposed on the pixel circuit layer and comprising a first light-emitting element and a second light-emitting element different from the first light-emitting element;
a reflective part disposed between the first light-emitting element and the second light-emitting element; and
a lens array comprising a first lens disposed on the first light-emitting element and a second lens disposed on the second light-emitting element,
an end portion of the reflective part comprises a first reflective part and a second reflective part extending symmetrically with respect to the first reflective part.

17. The display system of claim 16, wherein
the first lens has a convex shape having a first curvature, and
the first reflective part has a bent shape having a second curvature so as to be adjacent to the first lens.

18. The display system of claim 17, wherein a size of the first curvature and a size of the second curvature are same as each other.
